(19) United States
(12) Patent Application Publication
(10) Pub. No.: US 2017/0352711 A1
(43) Pub. Date: Dec. 7, 2017

(54) MANUFACTURING METHOD OF TFT BACKPLANE AND TFT BACKPLANE

(71) Applicant: Shenzhen China Star Optoelectronics Technology Co. Ltd., Shenzhen City (CN)

(72) Inventors: Xiaoxing Zhang, Shenzhen City (CN); Xingyu Zhou, Shenzhen City (CN); Yuanjun Hsu, Shenzhen City (CN)

(21) Appl. No.: 15/120,748

(22) PCT Filed: Jun. 27, 2016
(86) PCT No.: PCT/CN2016/087326

§ 371 Date: Aug. 23, 2016

(30) Foreign Application Priority Data
Jun. 7, 2016 (CN) 201610409643.0

(51) Int. Cl. H01L 27/32; H01L 51/00; H01L 51/52; H01L 51/56

(52) U.S. Cl. CPC H01L 27/3246; H01L 51/56; H01L 27/3248; H01L 51/0018; H01L 51/5237

(57) ABSTRACT

The present invention provides a manufacture method of a TFT backplate and a TFT backplate. By utilizing the oxide semiconductor to manufacture the switch TFT, and utilizing the advantages of rapid switch and lower leakage current of the oxide semiconductor, the switch speed of the switch TFT is raised and the leakage current is lowered; by utilizing the polysilicon to manufacture the drive TFT, and utilizing the properties of higher electron mobility and the uniform grain of the polysilicon, the electron mobility and the current output consistency of the drive TFT is promoted. These are beneficial for the promotion of the light uniformity of the OLED element.

### FIELD OF THE INVENTION

The present invention relates to a display technology field, and more particularly to a manufacture method of a TFT backplate and a TFT backplate.

### BACKGROUND OF THE INVENTION

The OLED (Organic Light-Emitting Diode) display, which is also named as the Organic light emitting display, is a new flat panel display device. Because it possesses advantages of simple manufacture process, low cost, low power consumption, high light emitting brightness, wide operating temperature range, thin volume, fast response speed, and being easy to achieve the color display and the large screen display, and being easy to achieve the match with the integrated circuit driver, and being easy to achieve the flexible display. Therefore, it has the broad application prospects.

The OLED can be categorized into two major types according to the driving ways, which are the Passive Matrix OLED (PMOLED) and the Active Matrix OLED (AMOLED), i.e. two types of the direct addressing and the Thin Film Transistor matrix addressing. The AMOLED comprises pixels arranged in array and belongs to active display type, which has high lighting efficiency and is generally utilized for the large scale display devices of high resolution.

The Thin Film Transistor (TFT) is the main drive element in the AMOLED display device, which directly relates with the development direction of the high performance flat panel display device. The thin film transistor has many structures. The materials for manufacturing the active layer of the thin film transistor having the corresponding structures are many, too. The Low Temperature Poly-silicon (LTPS) material is one of the preferred. Because the atom alignment of the Low Temperature Poly-silicon is regular and the carrier mobility is high. For the current drive type active matrix drive Organic light emitting display device, the Low Temperature Poly-silicon can better satisfies the requirement of the drive current.

At present, the LTPS is generally crystallized by the Excimer Laser Annealing (ELA) technology. The transient pulses of the laser are utilized to irradiate on the surface of the amorphous silicon layer to be melted and recrystallized. However, the ELA crystallization technology according to prior art cannot achieve effective control to the uniformity of the lattices and the crystallization direction of the lattices. The distribution of crystallization condition in the entire substrate is extremely nonuniform and results in that the long distance of the display effect image is not uniform, and the phenomena of uneven brightness (mura) appears.

The Oxide Semiconductor is the better TFT active layer manufacture material, and possesses properties of rapid switch and low leakage current but the electron mobility is slightly worse, which makes it slightly less in driving the OLED.

### SUMMARY OF THE INVENTION

An objective of the present invention is to provide a manufacture method of a TFT backplane, which can raise the switch speed of the TFT and reduce the leakage current, and meanwhile promote the electron mobility and the current output consistency of the drive TFT.

Another objective of the present invention is to provide a TFT backplane, in which the switch TFT can achieve the rapid switch and possesses lower leakage current, and the drive TFT has higher electron mobility and the current output consistency. These are beneficial for the promotion of the light uniformity of the OLED element.

For realizing the aforesaid objective, the present invention first provides a manufacture method of a TFT backplane, comprising steps of:

step 1, providing a substrate, and forming a first gate and a second gate which are separately located on the substrate, and depositing a gate insulation layer on the first gate, the second gate and the substrate, and depositing an amorphous silicon thin film on the gate insulation layer;

step 2, implementing boron ion doping to the amorphous silicon thin film, and then implementing a rapid thermal annealing process to the amorphous silicon thin film to convert the amorphous silicon film into a low temperature polysilicon film, wherein a doping concentration of boron ions in the low temperature polysilicon film gradually decreases from top to bottom;

step 3, patterning the low temperature polysilicon film to obtain a polysilicon layer correspondingly above the second gate;

step 4, forming an oxide semiconductor layer on the gate insulation layer correspondingly above the first gate;

step 5, forming a metal layer on the oxide semiconductor layer, the polysilicon layer and the gate insulation layer, and employing a halftone mask process to pattern the metal layer and the polysilicon layer to obtain a first source and a first drain, which are located on the oxide semiconductor layer and the gate insulation layer, and respectively contact with the two sides of the oxide semiconductor layer, and to obtain a second source and a second drain, which are located on the polysilicon layer and the gate insulation layer, and respectively contact with the two sides of the polysilicon layer, and meanwhile, forming a groove on the polysilicon layer corresponding to a region between the second source and the second drain to form a channel region on a portion of the polysilicon layer under the groove, and respectively forming a source contact region and a drain contact region in regions on the polysilicon layer at two sides of the channel region;

step 6, forming a passivation layer on the first source, the first drain, the second source, the second drain, the oxide semiconductor layer, the polysilicon layer and the gate insulation layer, and forming a flat layer on the passivation layer;

patterning the flat layer, the passivation layer and the gate insulation layer, and forming a first via correspondingly above the first drain and a second via correspondingly above the second drain in the flat layer and the passivation layer, and forming a third via correspondingly above the second gate in the flat layer, the passivation layer and the gate insulation layer;

step 7, forming a connection conductive layer and a pixel electrode on the flat layer, wherein the connection conductive layer respectively contacts with the first drain and the second gate through the first via and the third via, and thus to connect the first drain and the second gate, and the pixel electrode contacts with the second drain through the second via;

forming a pixel definition layer on the connection conductive layer, the pixel electrode and the flat layer, and patterning the pixel definition layer to obtain a fourth via correspondingly above the pixel electrode.

In the step 2, an annealing temperature of the rapid thermal annealing process is 600° C.-700° C. and an annealing time is 10 min-30 min.

The step 5 comprises:

step 51, forming a metal layer on the oxide semiconductor layer, the polysilicon layer and the gate insulation layer, and forming a photoresist layer on the metal layer, and employing a halftone mask process to implement exposure and development to the photoresist layer to obtain a first photoresist section, a second photoresist section and a third photoresist section;

providing a groove on the first photoresist section correspondingly above the oxide semiconductor layer, and a separation region between the second photoresist section and the third photoresist section correspondingly above the polysilicon layer.

step 52, employing a dry etching process to the first photoresist section, the second photoresist section, the third photoresist section, the metal layer and the polysilicon layer to obtain the first source, the first drain, the second source and the second drain, to form the groove on the polysilicon layer and to form the channel region on the portion of the polysilicon layer under the groove, and respectively forming a source contact region and a drain contact region in regions on the polysilicon layer at two sides of the channel region; then, stripping remained photoresist layer.

Etching gas employed in the dry etching process in the step 52 comprises one or more of sulfur hexafluoride, carbon tetrafluoride, oxygen and chlorine.

The manufacture method further comprises: step 8, forming an organic light emitting layer in the fourth via, and thus to obtain an OLED substrate.

Material of the oxide semiconductor layer comprises one or more of Indium Gallium Zinc Oxide and Indium Zinc Oxide.

The present invention further provides a TFT backplane, comprising a substrate, a first gate and a second gate, which are separately located on the substrate, a gate insulation layer located on the first gate, the second gate and the substrate, an oxide semiconductor layer and a polysilicon layer, which are located on the insulation layer and respectively correspond to the first gate and the second gate, a first source and a first drain, which are located on the oxide semiconductor layer and the gate insulation layer, and respectively contact with two sides of the oxide semiconductor layer, a second source and a second drain, which are respectively located on the polysilicon layer and the gate insulation layer, and respectively contact with two sides of the polysilicon layer, a passivation layer located on the first source, the first drain, the second source, the second drain, the oxide semiconductor layer, the polysilicon layer and the gate insulation layer, a flat layer located on the passivation layer, a connection conductive layer and a pixel electrode located on the flat layer, a pixel definition layer located on the connection conductive layer, the pixel electrode and the flat layer;

wherein a first via correspondingly above the first drain and a second via correspondingly above on the second drain are provided in the flat layer and passivation layer, and a third via correspondingly above the second gate is provided in the flat layer, the passivation layer and the gate insulation layer;

wherein the connection conductive layer respectively contacts with the first drain and the second gate through the first via and the third via, and thus to connect the first drain and the second gate, and the pixel electrode contacts with the second drain through the second via;

wherein the pixel definition layer further comprises a fourth via correspondingly above the pixel electrode;

wherein boron ion is doped in the polysilicon layer, and a doping concentration of boron ions in the polysilicon layer gradually decreases from top to bottom, and a groove is formed on the polysilicon layer corresponding to a region between the second source and the second drain, and a channel region is formed on a portion of the polysilicon layer under the groove, and a source contact region and a drain contact region in regions on the polysilicon layer are respectively formed at two sides of the channel region.

The TFT backplane further comprises an organic light emitting layer in the fourth via, and thus to form an OLED substrate.

Material of the oxide semiconductor layer comprises one or more of Indium Gallium Zinc Oxide and Indium Zinc Oxide.

The TFT backplane further comprises a buffer layer located between the substrate and the first gate, the second gate.

The present invention further provides a manufacture method of a TFT backplane, comprising steps of:

step 1, providing a substrate, and forming a first gate and a second gate which are separately located on the substrate, and depositing a gate insulation layer on the first gate, the second gate and the substrate, and depositing an amorphous silicon thin film on the gate insulation layer;

step 2, implementing boron ion doping to the amorphous silicon thin film, and then implementing a rapid thermal annealing process to the amorphous silicon thin film to convert the amorphous silicon film into a low temperature polysilicon film, wherein a doping concentration of boron ions in the low temperature polysilicon film gradually decreases from top to bottom;

step 3, patterning the low temperature polysilicon film to obtain a polysilicon layer correspondingly above the second gate;

step 4, forming an oxide semiconductor layer on the gate insulation layer correspondingly above the first gate;

step 5, forming a metal layer on the oxide semiconductor layer, the polysilicon layer and the gate insulation layer, and employing a halftone mask process to pattern the metal layer and the polysilicon layer to obtain a first source and a first drain, which are located on the oxide semiconductor layer and the gate insulation layer, and respectively contact with the two sides of the oxide semiconductor layer, and to obtain a second source and a second drain, which are located on the polysilicon layer and the gate insulation layer, and respectively contact with the two sides of the polysilicon layer, and meanwhile, forming a groove on the polysilicon layer corresponding to a region between the second source and the second drain to form a channel region on a portion of the polysilicon layer under the groove, and respectively forming a source contact region and a drain contact region in regions on the polysilicon layer at two sides of the channel region;

step 6, forming a passivation layer on the first source, the first drain, the second source, the second drain, the oxide semiconductor layer, the polysilicon layer and the gate insulation layer, and forming a flat layer on the passivation layer;

patterning the flat layer, the passivation layer and the gate insulation layer, and forming a first via correspondingly above the first drain and a second via correspondingly above the second drain in the flat layer and the passivation layer, and forming a third via correspondingly above the second gate in the flat layer, the passivation layer and the gate insulation layer;

step 7, forming a connection conductive layer and a pixel electrode on the flat layer, wherein the connection conductive layer respectively contacts with the first drain and the second gate through the first via and the third via, and thus to connect the first drain and the second gate, and the pixel electrode contacts with the second drain through the second via;

forming a pixel definition layer on the connection conductive layer, the pixel electrode and the flat layer, and patterning the pixel definition layer to obtain a fourth via correspondingly above the pixel electrode;

wherein in the step 2, an annealing temperature of the rapid thermal annealing process is 600° C.-700° C. and an annealing time is 10 min-30 min;

step 8, forming an organic light emitting layer in the fourth via, and thus to obtain an OLED substrate.

The benefits of the present invention are: the present invention provides a manufacture method of a TFT backplate and a TFT backplate. By utilizing the oxide semiconductor to manufacture the switch TFT, and utilizing the advantages of rapid switch and lower leakage current of the oxide semiconductor, the switch speed of the switch TFT is raised and the leakage current is lowered; by utilizing the polysilicon to manufacture the drive TFT, and utilizing the properties of higher electron mobility and the uniform grain of the polysilicon, the electron mobility and the current output consistency of the drive TFT is promoted. These are beneficial for the promotion of the light uniformity of the OLED element.

In order to better understand the characteristics and technical aspect of the invention, please refer to the following detailed description of the present invention is concerned with the diagrams, however, provide reference to the accompanying drawings and description only and is not intended to be limiting of the invention.

### BRIEF DESCRIPTION OF THE DRAWINGS

The technical solution and the beneficial effects of the present invention are best understood from the following detailed description with reference to the accompanying figures and embodiments.

In drawings,

FIG. 1 is a flowchart of the manufacture method of the TFT backplane according to the present invention;

FIG. 2 is a diagram of the step 1 in the manufacture method of the TFT backplane according to the present invention;

FIG. 3 is a diagram of the step 2 in the manufacture method of the TFT backplane according to the present invention;

FIG. 4 is a diagram of the step 3 in the manufacture method of the TFT backplane according to the present invention;

FIG. 5 is a diagram of the step 4 in the manufacture method of the TFT backplane according to the present invention;

FIGS. 6-7 are diagrams of the step 5 in the manufacture method of the TFT backplane according to the present invention;

FIG. 8 is a diagram of the step 6 in the manufacture method of the TFT backplane according to the present invention;

FIG. 9 is a diagram of the step 7 of the manufacture method of the TFT backplane according to the present invention and also a diagram of the TFT backplane according to the present invention.

### DETAILED DESCRIPTION OF PREFERRED EMBODIMENTS

For better explaining the technical solution and the effect of the present invention, the present invention will be further described in detail with the accompanying drawings and the specific embodiments.

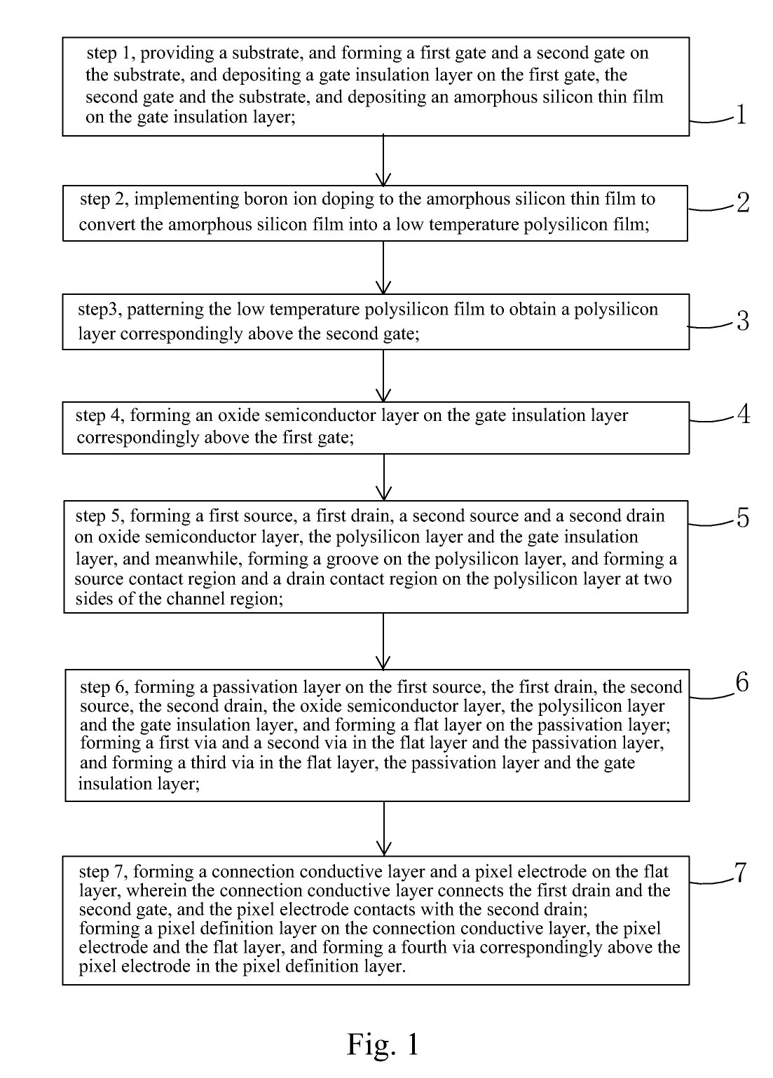

Please refer to FIG. 1. The present invention first provides a manufacture method of a TFT backplane, comprising steps of:

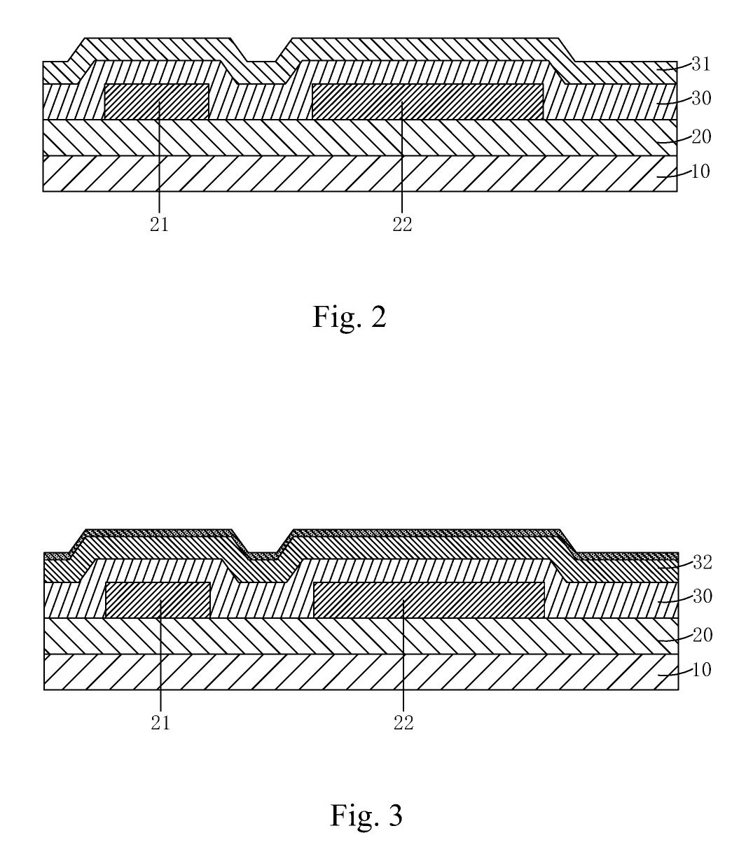

step 1, as shown in FIG. 2, providing a substrate 10, and forming a first gate 21 and a second gate 22 which are separately located on the substrate 10, and depositing a gate insulation layer 30 on the first gate 21, the second gate 22 and the substrate 10, and depositing an amorphous silicon thin film 31 on the gate insulation layer 30.

Specifically, the substrate 10 is a glass substrate.

Specifically, the step 1 further comprises: cleaning and baking the substrate 10 before depositing other structure layers on the substrate 10.

Preferably, the step 1 further comprises: depositing a buffer layer 20 on the substrate 10 before forming the first gate 21 and the second gate 22 on the substrate 10, and the first gate 21 and the second gate 22 are formed on the buffer layer 20, and the gate insulation layer 30 is deposited on the first gate 21, the second gate 22 and the buffer layer 20.

Specifically, the buffer layer 20 comprises a combination of one or two of a silicon nitride (SiNₓ) layer and a silicon oxide (SiOₓ) layer. Specifically, thicknesses of the silicon nitride layer and the silicon oxide layer respectively are 500 Å-2000 Å.

Specifically, the first gate 21 and the second gate 22 are composite layers formed by two molybdenum layers with one aluminum layer between the molybdenum layers, single molybdenum layers or single aluminum layers. Specifically, thicknesses of the first gate 21 and the second gate 22 respectively are 1500 Å-2000 Å.

Specifically, the gate insulation layer 30 comprises a combination of one or two of a silicon nitride layer and a silicon oxide layer.

step 2, as shown in FIG. 3, implementing boron ion doping to the amorphous silicon thin film 31, and then implementing a rapid thermal annealing process to the amorphous silicon thin film 31 to convert the amorphous silicon film 31 into a low temperature polysilicon film 32, wherein a doping concentration of boron ions in the low temperature polysilicon film 32 gradually decreases from top to bottom.

The present invention manufactures the low temperature polysilicon film with the boron ion Induced Solid Phase Crystallization. In comparison with the traditional Excimer Laser Annealing, the low temperature polysilicon film can have the better consistency. It is beneficial for raising the current output consistency of the drive TFT to raise the promotion level of the light uniformity of the OLED element.

Specifically, in the step 2, an annealing temperature of the rapid thermal annealing process is 600° C.-700° C. and an annealing time is 10 min-30 min.

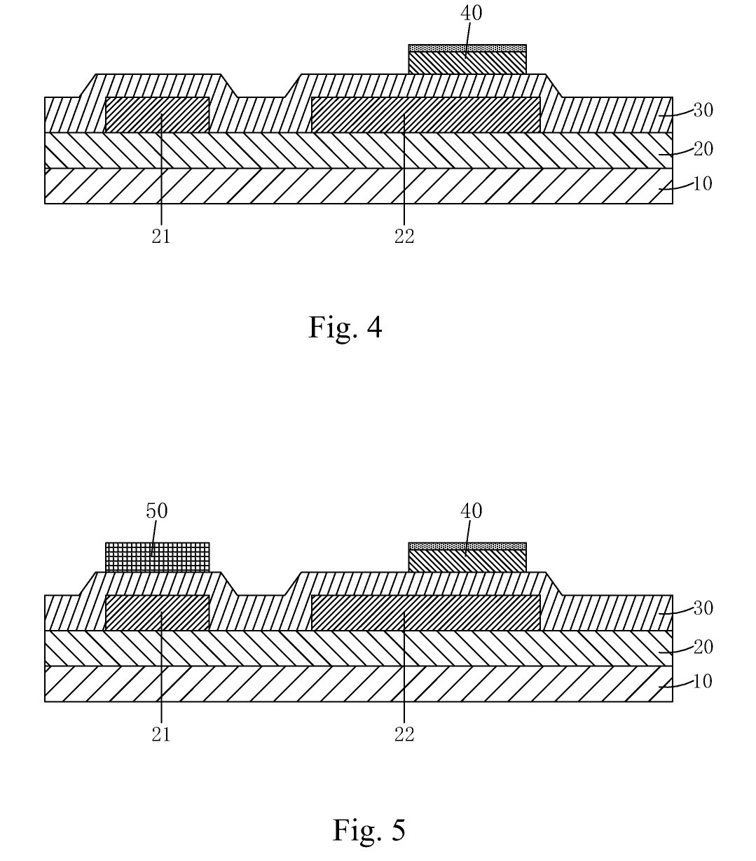

step 3, as shown in FIG. 4, patterning the low temperature polysilicon film 32 to obtain a polysilicon layer 40 correspondingly above the second gate 22.

step 4, as shown in FIG. 5, forming an oxide semiconductor layer 50 on the gate insulation layer 30 correspondingly above the first gate 21.

Specifically, material of the oxide semiconductor layer 50 comprises one or more of Indium Gallium Zinc Oxide (IGZO) and Indium Zinc Oxide (IZO).

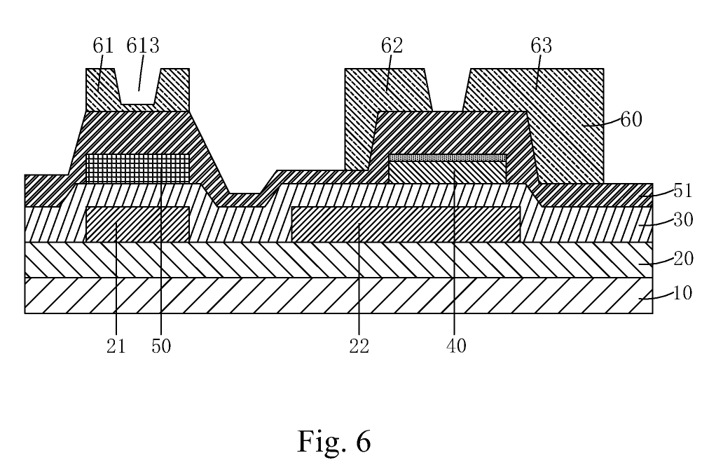

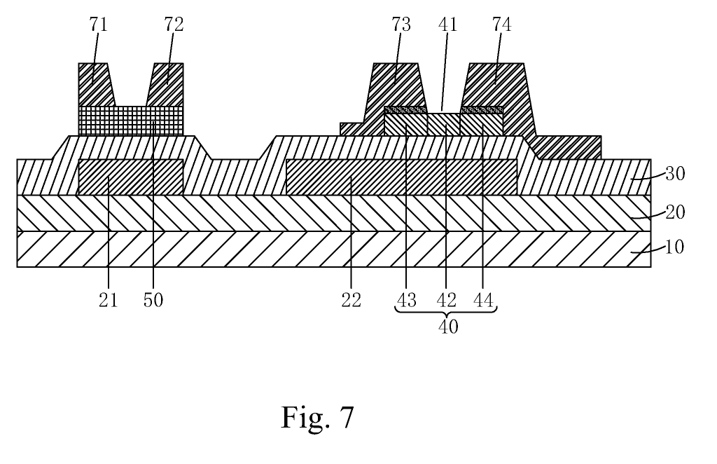

step 5, as shown in FIGS. 6-7, forming a metal layer 51 on the oxide semiconductor layer 50, the polysilicon layer 40 and the gate insulation layer 30, and employing a halftone mask process to pattern the metal layer 51 and the polysilicon layer 40 to obtain a first source 71 and a first drain 72, which are located on the oxide semiconductor layer 50 and the gate insulation layer 30, and respectively contact with the two sides of the oxide semiconductor layer 50, and to obtain a second source 73 and a second drain 74, which are located on the polysilicon layer 40 and the gate insulation layer 30, and respectively contact with the two sides of the polysilicon layer 40, and meanwhile, forming a groove 41 on the polysilicon layer 40 corresponding to a region between the second source 73 and the second drain 74 to form a channel region 42 on a portion of the polysilicon layer 40 under the groove 41, and respectively forming a source contact region 43 and a drain contact region 44 in regions on the polysilicon layer 40 at two sides of the channel region 42.

Specifically, in the step 5, by forming the groove 41 on the polysilicon layer 40 corresponding to the region between the second source 73 and the second drain 74 to remove the portion with the higher boron ion concentration above the region, and to save the portion with the lower boron ion concentration thereunder, the portion with the lower boron ion concentration is equivalent to the P type lightly doping region, and thus forms the channel region 42; the regions on the polysilicon layer 40 at the two sides of the channel region 42 still reserves the portion with the higher boron ion concentration, which is equivalent to the P type heavily doping region, and thus forms the source contact region 43 and the drain contact region 44, and the second source 73, the second drain 74, the polysilicon layer 40 and the second gate 22 construct a P type thin film transistor.

Specifically, the step 5 comprises:

step 51, as shown in FIG. 6, forming a metal layer 51 on the oxide semiconductor layer 50, the polysilicon layer 40 and the gate insulation layer 30, and forming a photoresist layer 60 on the metal layer 51, and employing a halftone mask process to implement exposure and development to the photoresist layer 60 to obtain a first photoresist section 61, a second photoresist section 62 and a third photoresist section 63;

providing a groove 613 on the first photoresist section 61 correspondingly above the oxide semiconductor layer 50, and a separation region between the second photoresist section 62 and the third photoresist section 63 correspondingly above the polysilicon layer 40.

step 52, as shown in FIG. 7, employing a dry etching process to the first photoresist section 61, the second photoresist section 62, the third photoresist section 63, the metal layer 51 and the polysilicon layer 40 to obtain the first source 71, the first drain 72, the second source 73 and the second drain 74, to form the groove 41 on the polysilicon layer 40 and to form the channel region 42 on the portion of the polysilicon layer 40 under the groove 41, and respectively forming a source contact region 43 and a drain contact region 44 in regions on the polysilicon layer 40 at two sides of the channel region 42; then, stripping remained photoresist layer 60.

Specifically, etching gas employed in the dry etching process in the step 52 comprises one or more of sulfur hexafluoride (SF₆), carbon tetrafluoride (CF₄), oxygen (O₂) and chlorine (Cl₂).

Specifically, the first source 71, the first drain 72, the second source 73 and the second drain 74 are composite layers formed by two molybdenum layers with one aluminum layer between the molybdenum layers, single molybdenum layers or single aluminum layers. Specifically, thicknesses of the first source 71, the first drain 72, the second source 73 and the second drain 74 respectively are 1500 Å-2000 Å.

Specifically, the first gate 21, the oxide semiconductor layer 50, the first source 71 and the first drain 72 construct a switch TFT, and the second gate 22, the polysilicon layer 40, the second source 73 and the second drain 74 construct a drive TFT.

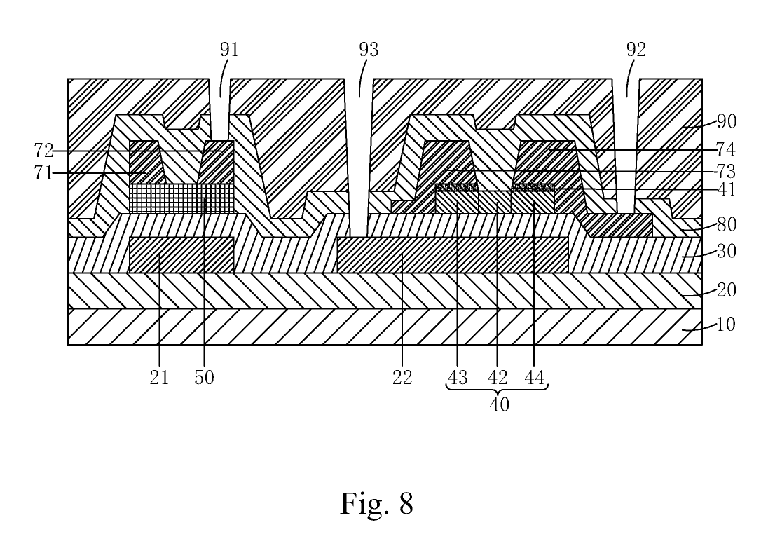

step 6, as shown in FIG. 8, forming a passivation layer 80 on the first source 71, the first drain 72, the second source 73, the second drain 74, the oxide semiconductor layer 50, the polysilicon layer 40 and the gate insulation layer 30, and forming a flat layer 90 on the passivation layer 80;

patterning the flat layer 90, the passivation layer 80 and the gate insulation layer 30, and forming a first via 91 correspondingly above the first drain 72 and a second via 92 correspondingly above the second drain 74 in the flat layer 90 and the passivation layer 80, and forming a third via 93 correspondingly above the second gate 22 in the flat layer 90, the passivation layer 80 and the gate insulation layer 30.

Specifically, the passivation layer 80 comprises a combination of one or two of a silicon nitride layer and a silicon oxide layer.

Specifically, the flat layer 90 is organic material.

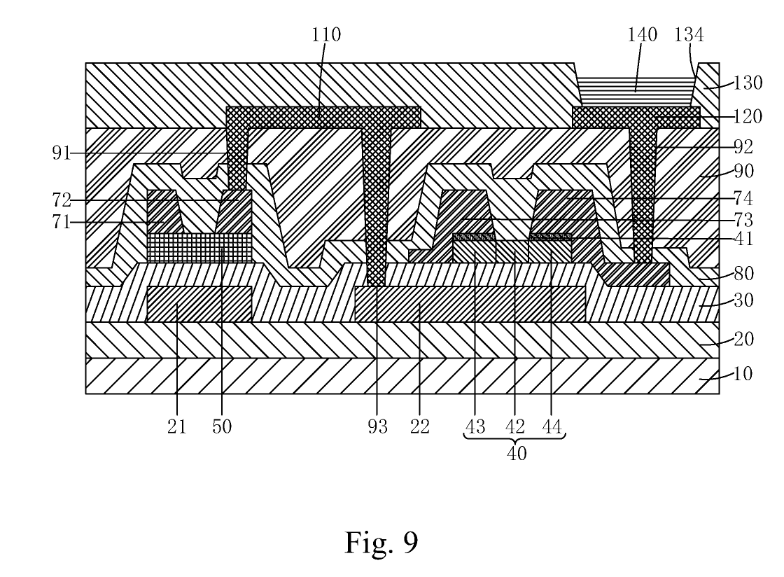

step 7, as shown in FIG. 9, forming a connection conductive layer 110 and a pixel electrode 120 on the flat layer 90, wherein the connection conductive layer 110 respectively contacts with the first drain 72 and the second gate 22 through the first via 91 and the third via 93, and thus to connect the first drain 72 and the second gate 22, and the pixel electrode 120 contacts with the second drain 74 through the second via 92;

forming a pixel definition layer 130 on the connection conductive layer 110, the pixel electrode 120 and the flat layer 90, and patterning the pixel definition layer 130 to obtain a fourth via 134 correspondingly above the pixel electrode 120.

Specifically, both materials of the connection conductive layer 110 and the pixel electrode 120 are transparent conductive metal oxide, and preferably to be Indium Tin Oxide (ITO).

Specifically, the pixel define layer 130 is organic material.

Specifically, the present invention further comprises: step 8, forming an organic light emitting layer 140 in the fourth via 134, and thus to obtain an OLED substrate.

In the aforesaid manufacture method of the TFT backplate, by utilizing the oxide semiconductor to manufacture the switch TFT, and utilizing the advantages of rapid switch and lower leakage current of the oxide semiconductor, the switch speed of the switch TFT is raised and the leakage current is lowered; by utilizing the polysilicon to manufacture the drive TFT, and utilizing the properties of higher electron mobility and the uniform grain of the polysilicon, the electron mobility and the current output consistency of the drive TFT is promoted. These are beneficial for the promotion of the light uniformity of the OLED element.

Please refer to FIG. 9. Based on the aforesaid manufacture method of the TFT backplane, the present invention further provides a TFT backplane, comprising a substrate 10, a first gate 21 and a second gate 22, which are separately located on the substrate 10, a gate insulation layer 30 located on the first gate 21, the second gate 22 and the substrate 10, an oxide semiconductor layer 50 and a polysilicon layer 40, which are located on the insulation layer 30 and respectively correspond to the first gate 21 and the second gate 22, a first source 71 and a first drain 72, which are located on the oxide semiconductor layer 50 and the gate insulation layer 30, and respectively contact with two sides of the oxide semiconductor layer 50, a second source 73 and a second drain 74, which are respectively located on the polysilicon layer 40 and the gate insulation layer 30, and respectively contact with two sides of the polysilicon layer 40, a passivation layer 80 located on the first source 71, the first drain 72, the second source 73, the second drain 74, the oxide semiconductor layer 50, the polysilicon layer 40 and the gate insulation layer 30, a flat layer 90 located on the passivation layer 80, a connection conductive layer 110 and a pixel electrode 120 located on the flat layer 90, a pixel definition layer 130 located on the connection conductive layer 110, the pixel electrode 120 and the flat layer 90;

wherein a first via 91 correspondingly above the first drain 72 and a second via 92 correspondingly above on the second drain 74 are provided in the flat layer 90 and passivation layer 80, and a third via 93 correspondingly above the second gate 22 is provided in the flat layer 90, the passivation layer 80 and the gate insulation layer 30;

wherein the connection conductive layer 110 respectively contacts with the first drain 72 and the second gate 22 through the first via 91 and the third via 93, and thus to connect the first drain 72 and the second gate 22, and the pixel electrode 120 contacts with the second drain 74 through the second via 92;

wherein the pixel definition layer 130 further comprises a fourth via 134 correspondingly above the pixel electrode 120;

wherein boron ion is doped in the polysilicon layer 40, and a doping concentration of boron ions in the polysilicon layer 40 gradually decreases from top to bottom, and a groove 41 is formed on the polysilicon layer 40 corresponding to a region between the second source 73 and the second drain 74, and a channel region 42 is formed on a portion of the polysilicon layer 40 under the groove 41, and a source contact region 43 and a drain contact region 44 in regions on the polysilicon layer 40 are respectively formed at two sides of the channel region 42.

Specifically, the TFT backplane further comprises an organic light emitting layer 140 in the fourth via 134, and thus to form an OLED substrate.

Preferably, the TFT backplane further comprises a buffer layer 20 located between the substrate 10 and the first gate 21, the second gate 22.

Specifically, the substrate 10 is a glass substrate.

Specifically, the buffer layer 20 comprises a combination of one or two of a silicon nitride layer and a silicon oxide layer. Specifically, thicknesses of the silicon nitride layer and the silicon oxide layer respectively are 500 Å-2000 Å.

Preferably, the first gate 21 and the second gate 22 are composite layers formed by two molybdenum layers with one aluminum layer between the molybdenum layers, single molybdenum layers or single aluminum layers. Specifically, thicknesses of the first gate 21 and the second gate 22 respectively are 1500 Å-2000 Å.

Specifically, the gate insulation layer 30 comprises a combination of one or two of a silicon nitride layer and a silicon oxide layer.

Specifically, material of the oxide semiconductor layer 50 comprises one or more of Indium Gallium Zinc Oxide and Indium Zinc Oxide.

Specifically, the first source 71, the first drain 72, the second source 73 and the second drain 74 are composite layers formed by two molybdenum layers with one aluminum layer between the molybdenum layers, single molybdenum layers or single aluminum layers. Specifically, thicknesses of the first source 71, the first drain 72, the second source 73 and the second drain 74 respectively are 1500 Å-2000 Å.

Specifically, the passivation layer 80 comprises a combination of one or two of a silicon nitride layer and a silicon oxide layer.

Specifically, the flat layer 90 is organic material.

Specifically, both materials of the connection conductive layer 110 and the pixel electrode 120 are transparent conductive metal oxide, and preferably to be Indium Tin Oxide.

Specifically, the pixel define layer 130 is organic material.

In the aforesaid TFT backplate, by utilizing the oxide semiconductor to manufacture the switch TFT, and utilizing the advantages of rapid switch and lower leakage current of the oxide semiconductor, the switch speed of the switch TFT is raised and the leakage current is lowered; by utilizing the polysilicon to manufacture the drive TFT, and utilizing the properties of higher electron mobility and the uniform grain of the polysilicon, the electron mobility and the current output consistency of the drive TFT is promoted. These are beneficial for the promotion of the light uniformity of the OLED element.

In conclusion, the present invention provides a manufacture method of a TFT backplate and a TFT backplate. By utilizing the oxide semiconductor layer to manufacture the switch TFT, and utilizing the advantages of rapid switch and lower leakage current of the oxide semiconductor, the switch speed of the switch TFT is raised and the leakage current is lowered; by utilizing the polysilicon layer to manufacture the drive TFT, and utilizing the properties of higher electron mobility and the uniform grain of the polysilicon layer, the electron mobility and the current output consistency of the drive TFT is promoted. These are beneficial for the promotion of the light uniformity of the OLED element.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A manufacture method of a TFT backplane, comprising steps of:
step 1, providing a substrate, and forming a first gate and a second gate which are separately located on the substrate, and depositing a gate insulation layer on the first gate, the second gate and the substrate, and depositing an amorphous silicon thin film on the gate insulation layer;
step 2, implementing boron ion doping to the amorphous silicon thin film, and then implementing a rapid thermal annealing process to the amorphous silicon thin film to convert the amorphous silicon film into a low temperature polysilicon film, wherein a doping concentration of boron ions in the low temperature polysilicon film gradually decreases from top to bottom;
step 3, patterning the low temperature polysilicon film to obtain a polysilicon layer correspondingly above the second gate;
step 4, forming an oxide semiconductor layer on the gate insulation layer correspondingly above the first gate;
step 5, forming a metal layer on the oxide semiconductor layer, the polysilicon layer and the gate insulation layer, and employing a halftone mask process to pattern the metal layer and the polysilicon layer to obtain a first source and a first drain, which are located on the oxide semiconductor layer and the gate insulation layer, and respectively contact with the two sides of the oxide semiconductor layer, and to obtain a second source and a second drain, which are located on the polysilicon layer and the gate insulation layer, and respectively contact with the two sides of the polysilicon layer, and meanwhile, forming a groove on the polysilicon layer corresponding to a region between the second source and the second drain to form a channel region on a portion of the polysilicon layer under the groove, and respectively forming a source contact region and a drain contact region in regions on the polysilicon layer at two sides of the channel region;
step 6, forming a passivation layer on the first source, the first drain, the second source, the second drain, the oxide semiconductor layer, the polysilicon layer and the gate insulation layer, and forming a flat layer on the passivation layer;
patterning the flat layer, the passivation layer and the gate insulation layer, and forming a first via correspondingly above the first drain and a second via correspondingly above the second drain in the flat layer and the passivation layer, and forming a third via correspondingly above the second gate in the flat layer, the passivation layer and the gate insulation layer;
step 7, forming a connection conductive layer and a pixel electrode on the flat layer, wherein the connection conductive layer respectively contacts with the first drain and the second gate through the first via and the third via, and thus to connect the first drain and the second gate, and the pixel electrode contacts with the second drain through the second via;
forming a pixel definition layer on the connection conductive layer, the pixel electrode and the flat layer, and patterning the pixel definition layer to obtain a fourth via correspondingly above the pixel electrode.

2. The manufacture method of the TFT backplane according to claim 1, wherein in the step 2, an annealing temperature of the rapid thermal annealing process is 600° C.-700° C. and an annealing time is 10 min-30 min.

3. The manufacture method of the TFT backplane according to claim 1, wherein the step 5 comprises:
step 51, forming a metal layer on the oxide semiconductor layer, the polysilicon layer and the gate insulation layer, and forming a photoresist layer on the metal layer, and employing a halftone mask process to implement exposure and development to the photoresist layer to obtain a first photoresist section, a second photoresist section and a third photoresist section;
providing a groove on the first photoresist section correspondingly above the oxide semiconductor layer, and a separation region between the second photoresist section and the third photoresist section correspondingly above the polysilicon layer;
step 52, employing a dry etching process to the first photoresist section, the second photoresist section, the third photoresist section, the metal layer and the polysilicon layer to obtain the first source, the first drain, the second source and the second drain, to form the groove on the polysilicon layer and to form the channel region on the portion of the polysilicon layer under the groove, and respectively forming a source contact region and a drain contact region in regions on the polysilicon layer at two sides of the channel region; then, stripping remained photoresist layer.

4. The manufacture method of the TFT backplane according to claim 3, wherein etching gas employed in the dry etching process in the step 52 comprises one or more of sulfur hexafluoride, carbon tetrafluoride, oxygen and chlorine.

5. The manufacture method of the TFT backplane according to claim 1, further comprising step 8, forming an organic light emitting layer in the fourth via, and thus to obtain an OLED substrate.

6. The manufacture method of the TFT backplane according to claim 1, wherein material of the oxide semiconductor layer comprises one or more of Indium Gallium Zinc Oxide and Indium Zinc Oxide.

7. A TFT backplane, comprising a substrate, a first gate and a second gate, which are separately located on the substrate, a gate insulation layer located on the first gate, the second gate and the substrate, an oxide semiconductor layer and a polysilicon layer, which are located on the insulation layer and respectively correspond to the first gate and the second gate, a first source and a first drain, which are located on the oxide semiconductor layer and the gate insulation layer, and respectively contact with two sides of the oxide semiconductor layer, a second source and a second drain, which are respectively located on the polysilicon layer and the gate insulation layer, and respectively contact with two sides of the polysilicon layer, a passivation layer located on the first source, the first drain, the second source, the second drain, the oxide semiconductor layer, the polysilicon layer and the gate insulation layer, a flat layer located on the passivation layer, a connection conductive layer and a pixel electrode located on the flat layer, a pixel definition layer located on the connection conductive layer, the pixel electrode and the flat layer;
wherein a first via correspondingly above the first drain and a second via correspondingly above on the second drain are provided in the flat layer and passivation layer, and a third via correspondingly above the second gate is provided in the flat layer, the passivation layer and the gate insulation layer;
wherein the connection conductive layer respectively contacts with the first drain and the second gate through the first via and the third via, and thus to connect the first drain and the second gate, and the pixel electrode contacts with the second drain through the second via;
wherein the pixel definition layer further comprises a fourth via correspondingly above the pixel electrode;
wherein boron ion is doped in the polysilicon layer, and a doping concentration of boron ions in the polysilicon layer gradually decreases from top to bottom, and a groove is formed on the polysilicon layer corresponding to a region between the second source and the second drain, and a channel region is formed on a portion of the polysilicon layer under the groove, and a source contact region and a drain contact region in regions on the polysilicon layer are respectively formed at two sides of the channel region.

8. The TFT backplane according to claim 7, further comprising an organic light emitting layer in the fourth via, and thus to form an OLED substrate.

9. The TFT backplane according to claim 7, wherein material of the oxide semiconductor layer comprises one or more of Indium Gallium Zinc Oxide and Indium Zinc Oxide.

10. The TFT backplane according to claim 7, further comprising a buffer layer located between the substrate and the first gate, the second gate.

11. A manufacture method of a TFT backplane, comprising steps of:
step 1, providing a substrate, and forming a first gate and a second gate which are separately located on the substrate, and depositing a gate insulation layer on the first gate, the second gate and the substrate, and depositing an amorphous silicon thin film on the gate insulation layer;
step 2, implementing boron ion doping to the amorphous silicon thin film, and then implementing a rapid thermal annealing process to the amorphous silicon thin film to convert the amorphous silicon film into a low temperature polysilicon film, wherein a doping concentration of boron ions in the low temperature polysilicon film gradually decreases from top to bottom;
step 3, patterning the low temperature polysilicon film to obtain a polysilicon layer correspondingly above the second gate;
step 4, forming an oxide semiconductor layer on the gate insulation layer correspondingly above the first gate;
step 5, forming a metal layer on the oxide semiconductor layer, the polysilicon layer and the gate insulation layer, and employing a halftone mask process to pattern the metal layer and the polysilicon layer to obtain a first source and a first drain, which are located on the oxide semiconductor layer and the gate insulation layer, and respectively contact with the two sides of the oxide semiconductor layer, and to obtain a second source and a second drain, which are located on the polysilicon layer and the gate insulation layer, and respectively contact with the two sides of the polysilicon layer, and meanwhile, forming a groove on the polysilicon layer corresponding to a region between the second source and the second drain to form a channel region on a portion of the polysilicon layer under the groove, and respectively forming a source contact region and a drain contact region in regions on the polysilicon layer at two sides of the channel region;
step 6, forming a passivation layer on the first source, the first drain, the second source, the second drain, the oxide semiconductor layer, the polysilicon layer and the gate insulation layer, and forming a flat layer on the passivation layer;
patterning the flat layer, the passivation layer and the gate insulation layer, and forming a first via correspondingly above the first drain and a second via correspondingly above the second drain in the flat layer and the passivation layer, and forming a third via correspondingly above the second gate in the flat layer, the passivation layer and the gate insulation layer;
step 7, forming a connection conductive layer and a pixel electrode on the flat layer, wherein the connection conductive layer respectively contacts with the first drain and the second gate through the first via and the third via, and thus to connect the first drain and the second gate, and the pixel electrode contacts with the second drain through the second via;
forming a pixel definition layer on the connection conductive layer, the pixel electrode and the flat layer, and patterning the pixel definition layer to obtain a fourth via correspondingly above the pixel electrode;
wherein in the step 2, an annealing temperature of the rapid thermal annealing process is 600° C.-700° C. and an annealing time is 10 min-30 min;
step 8, forming an organic light emitting layer in the fourth via, and thus to obtain an OLED substrate.

12. The manufacture method of the TFT backplane according to claim 11, wherein the step 5 comprises:
step 51, forming a metal layer on the oxide semiconductor layer, the polysilicon layer and the gate insulation layer, and forming a photoresist layer on the metal layer, and employing a halftone mask process to implement exposure and development to the photoresist layer to obtain a first photoresist section, a second photoresist section and a third photoresist section;
providing a groove on the first photoresist section correspondingly above the oxide semiconductor layer, and a separation region between the second photoresist section and the third photoresist section correspondingly above the polysilicon layer;
step 52, employing a dry etching process to the first photoresist section, the second photoresist section, the third photoresist section, the metal layer and the polysilicon layer to obtain the first source, the first drain, the second source and the second drain, to form the groove on the polysilicon layer and to form the channel region on the portion of the polysilicon layer under the groove, and respectively forming a source contact region and a drain contact region in regions on the polysilicon layer at two sides of the channel region; then, stripping remained photoresist layer.

13. The manufacture method of the TFT backplane according to claim 12, wherein etching gas employed in the dry etching process in the step 52 comprises one or more of sulfur hexafluoride, carbon tetrafluoride, oxygen and chlorine.

14. The manufacture method of the TFT backplane according to claim 11, wherein material of the oxide semiconductor layer comprises one or more of Indium Gallium Zinc Oxide and Indium Zinc Oxide.
